(19) United States
(12) Patent Application Publication
(10) Pub. No.: US 2018/0160533 A1
(43) Pub. Date: Jun. 7, 2018

(54) MULTILAYER PRINTED CIRCUIT BOARD

(71) Applicant: KINSUS INTERCONNECT TECHNOLOGY CORP., Taoyuan City (TW)

(72) Inventors: Ting-Hao LIN, Taoyuan City (TW); Chiao-Cheng CHANG, Taoyuan City (TW); Yi-Nong LIN, Taoyuan City (TW)

(73) Assignee: KINSUS INTERCONNECT TECHNOLOGY CORP., Taoyuan City (TW)

(21) Appl. No.: 15/369,822

(22) Filed: Dec. 5, 2016

(51) Int. Cl. H05K 1/14; H05K 1/02; H05K 3/36; H05K 3/46

(52) U.S. Cl. CPC H05K 1/144; H05K 1/0298; H05K 3/366; H05K 2203/041; H05K 2201/041; H05K 2201/10234; H05K 3/46

(57) ABSTRACT

A multilayer printed circuit board includes a first circuit board, a second circuit board and bonding films. The first circuit board includes a first dielectric layer, a first wiring pattern layer, a plurality of conductive blocks and a plurality of solder balls. The first wiring pattern layer is formed on a first surface of the first dielectric layer and the conductive blocks are formed on a second surface of the first dielectric layer. The solder balls are formed on a surface of the first wiring pattern layer. The second circuit board includes a second dielectric layer, a second wiring pattern layer, second conductive blocks and conductive pillars. The second wiring pattern layer is formed on a third surface of the second dielectric layer and the second conductive blocks are formed on a fourth surface thereof. The conductive pillars are formed on the second wiring pattern layer.

### BACKGROUND OF THE INVENTION

### 1. Field of the Invention

The present invention relates to a multilayer printed circuit board, and more particularly to a multilayer printed circuit board to prevent solder balls from overflowing.

### 2. Description of Related Art

With a minimizing trend of electronic devices, routing of a circuitry of the electronic device becomes more and more concentrated. When the circuitry is more and more concentrated, the routing for the signal becomes more complicated. If all wires are to be located at one layer of a printed circuit board, all of the wires are not easily disposed on the one single layer and may be very densely disposed to cause signal interference. Therefore, a new design for a multilayer printed circuit board is required. The following description is about how to manufacture the conventional multilayer printed circuit board.

With reference to FIG. 4A, a first conductive layer 51 and a second conductive layer 52 are respectively formed on a first surface 41 and a second surface 42 of a releasing layer 40.

With reference to FIG. 4B, a few procedures, such as coating a dry film, developing, electroplating, washing and so on, are performed on the first conductive layer 51 and the second conductive layer 52 to form a first wiring pattern layer 53 on a surface of the first conductive layer 51 and a second wiring pattern layer 54 on the surface of the second conductive layer 52.

With reference to FIG. 4C, a first dielectric layer 55 is formed on the surfaces of the first conductive layer 51 and the first wiring pattern layer 53, and a second dielectric layer 56 is formed on the surfaces of the second conductive layer 52 and the second wiring pattern layer 54.

Thereafter, with reference to FIG. 4D, a plurality of cavities 57 are formed in the first dielectric layer 55 and the second dielectric layer 56 by a laser process. The first wiring pattern layer 53 and the second wiring pattern layer 54 are exposed from the notches 57.

Then, with reference to FIG. 4E, a third conductive layer 58 and a fourth conductive layer 59 are formed on the surfaces of the first wiring pattern layer 53 and the second wiring pattern layer 54 by procedures, such as coating the dry film, developing, electroplating, washing, etc., on the first dielectric layer 55 and the second dielectric layer 56. The manufacture of a first circuit board 60 and a second circuit board 70 is finished.

With reference to FIG. 4F, two dry films 80 are respectively formed on the surfaces of the first circuit board 60 and the second circuit board 70 to protect the first circuit board 60 and the second circuit board 70 so as to prevent the damage of the first circuit board 60 and the second circuit board 70 in a subsequent separation step. Thereafter, the separation step is performed to release the first circuit board 60 and the second circuit board 70 from the surfaces of the releasing layer 40.

Then, with reference to FIG. 4G, a portion of the dry films 80 is removed from the first circuit board 60 to perform a surface treatment on the surface of the third conductive layer 58. And also, with reference to FIG. 4H, a portion of the dry films 80 is removed from the second circuit board 70 to perform the surface treatment on the surface of the second wiring pattern layer 54. By the surface treatment, adhesion force is increased on the third conductive layer 58 and the second wiring pattern layer 54. Therefore, the third conductive layer 58 and the second wiring pattern layer 54 are easy to adhere to other conductive materials.

With reference to FIG. 4I, the dry films 80 are completely removed from the surface of the first conductive layer 51 of the first circuit board 60. With reference to FIG. 4J, the dry films 80 are completely removed from the surface of the second conductive layer 52 of the second circuit board 70. The steps to remove the dry films 80 are to prevent occurrence of a short circuit in the first circuit board 60 or the second circuit board 70.

With reference to FIG. 4L, a plurality of solder balls 91 are formed on the surface of the first wiring pattern layer 53. The solder balls 91 are formed on the surface of the first wiring pattern layer 53 by dispensing solder paste.

With reference to FIG. 4M, a few bonding films 92 are formed on the surface of the second dielectric layer 56. A bonding layer is coated on the surface of the second dielectric layer 56 and a portion of the bonding layer is removed to form the bonding films 92 at two sides of the second wiring pattern layer 54. A cavity 93 is formed between two of the bonding films 92 and the cavity 93 is located on the surface of the second wiring pattern layer 54.

With reference to FIG. 4N, the first circuit board 60 and the second circuit board 70 are bonded together, and the solder balls 91 of the first circuit board 60 are correspondingly and respectively integrated with the cavities 93 of the second circuit board 70. The first circuit board 60 and the second circuit board 70 are bonded together by the bonding films 92. When the first circuit board 60 and the second circuit board 70 are bonded together, the solder balls 91 are filled within the cavities 93 respectively, as shown in FIG. 4O.

At last, with reference to FIG. 4P, the surface treatment is performed on the surfaces of the first circuit board 60 and the second circuit board 70 after bonding the first circuit board 60 and the second circuit board 70 together. For example, a protecting film 94 is formed on the surfaces of the first circuit board 60 and the second circuit board 60 to avoid hitting or damaging the multilayer printed circuit board. The conventional multilayer printed circuit board is thus manufactured.

However, due to the minimization trend of the electronic devices, the usage of the solder balls is hard to control, and the solder balls are over used and overflowed from the cavity during the bonding procedure. Therefore, the surfaces of the first circuit board and the second circuit board are polluted, affecting the conductivity or generating a short circuit in the multilayer printed circuit board. Accordingly, a solder overflowing problem in the multilayer printed circuit board needs to be improved so as to prevent the occurrence of the short circuit.

### SUMMARY OF THE INVENTION

An objective of the present invention is to provide a multilayer printed circuit board to reduce the usage of solder balls and overcome the solder overflowing problem. Therefore, occurrence of a short circuit in the multilayer printed circuit board can be avoided.

In order to achieve the aforementioned purpose, the present invention provides a multilayer printed circuit board including a first circuit board, a second circuit board and a plurality of bonding films.

The first circuit board includes a first dielectric layer, a first wiring pattern layer, a plurality of conductive blocks, and a plurality of solder balls. The first dielectric layer has a first surface and a second surface. The first wiring pattern layer is formed on the first surface of the first dielectric layer. The conductive blocks are formed on the second surface of the first dielectric layer and electrically connected to the first wiring pattern layer. The solder balls are formed on a surface of the first wiring pattern layer and electrically connected to the first wiring pattern layer.

The second circuit board includes a second dielectric layer, a second wiring pattern layer, a plurality of second conductive blocks, and a plurality of conductive pillars. The second dielectric layer has a third surface and a fourth surface. The second wiring pattern layer is formed on the third surface of the second dielectric layer. The second conductive blocks are formed on the fourth surface of the second dielectric layer and electrically connected to the second wiring pattern layer. The conductive pillars are formed on the surface of the second wiring pattern layer and electrically connected to the second wiring pattern layer. The bonding films are formed on the second circuit board for bonding the first circuit board and the second circuit board. The solder balls and the conductive pillars are correspondingly integrated together to conduct the first wiring pattern layer and the second wiring pattern layer when the first circuit board and the second circuit board are bonded together.

The advantage in the present invention is to reduce the usage of the solder balls by implementation of the conductive pillars. Therefore, the solder overflowing problem can be avoided when the first circuit board and the second circuit board are bonded together.

### BRIEF DESCRIPTION OF THE DRAWINGS

FIG. 1 is a flowchart of a manufacturing method for a multilayer printed circuit board in the present invention;

FIG. 2A-FIG. 2H are schematic views showing manufacturing procedures of the multilayer printed circuit board in the present invention;

FIG. 3A is an exploded view of the multilayer printed circuit board in the present invention;

FIG. 3B is a plan view of the multilayer printed circuit board in the present invention; and

FIG. 4A-FIG. 4P are schematic views showing manufacturing procedures of the conventional multilayer printed circuit board.

### DETAILED DESCRIPTION OF THE PREFERRED EMBODIMENT

These and other aspects of the embodiments herein will be better appreciated and understood when considered in conjunction with the following description and the accompanying drawings.

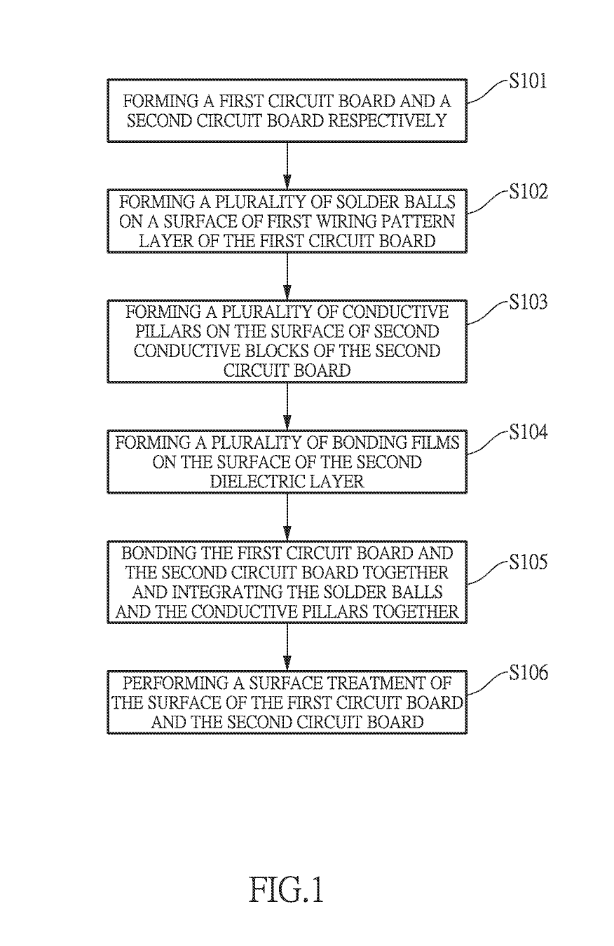

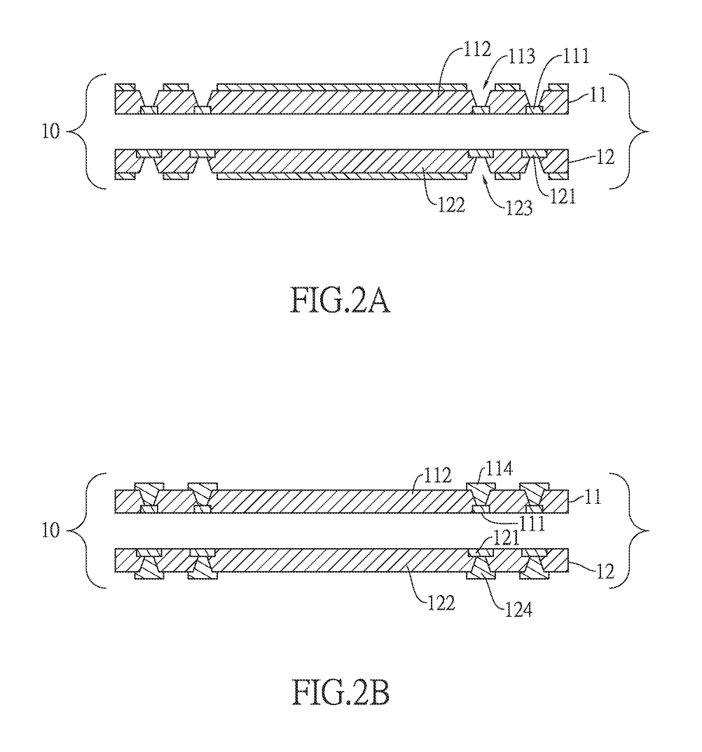

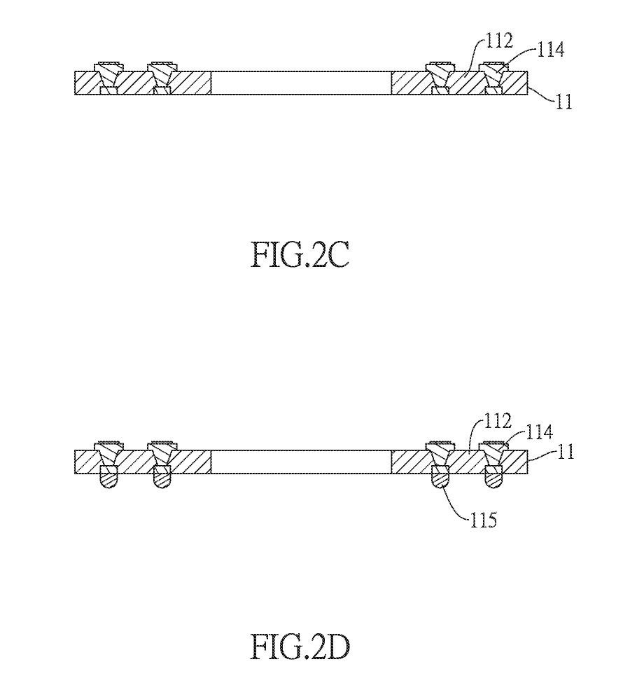

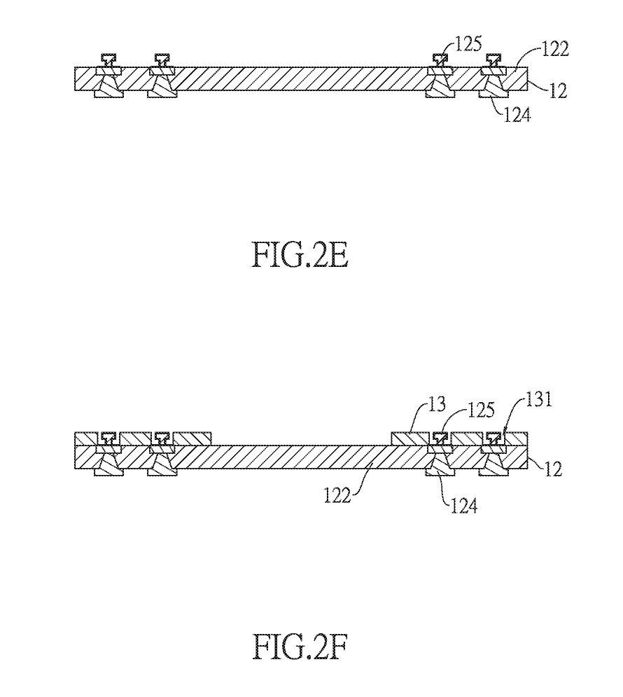

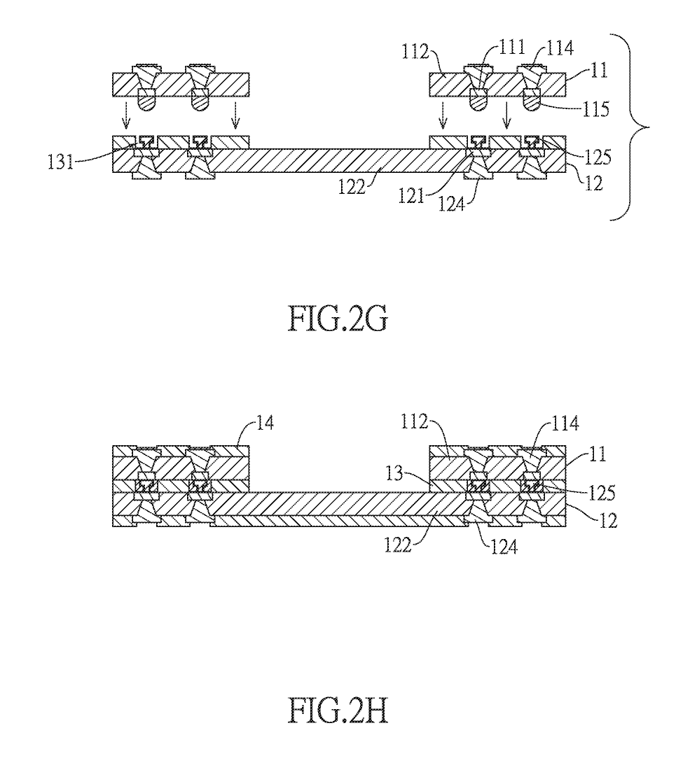

With reference to FIG. 1 and FIG. 2A to FIG. 2H, a manufacturing method for a multilayer printed circuit board 10 is disclosed in the present invention. In step S101, a first circuit board 11 and a second circuit board 12 are formed respectively, as shown in FIG. 2A. A first wiring pattern layer 111 is formed on the first circuit board 11 and a second wiring pattern layer 121 is formed on the second circuit board 12 firstly. Then, a first dielectric layer 112 and a second dielectric layer 122 are formed respectively on surfaces of the first wiring pattern layer 111 and the second wiring pattern layer 121. A plurality of first notches 113 and a plurality of second notches 123 are respectively formed in the first dielectric layer 112 and the second dielectric layer 122 by a laser procedure to expose portions of the first wiring pattern layer 111 and portions of the second wiring pattern layer 121. Thereafter, as shown in FIG. 2B, a plurality of first conductive blocks 114 are formed within the first notches 113 by an electroplating procedure and disposed on the first wiring pattern layer 111. A plurality of second conductive blocks 124 are formed within the second notches 123 and disposed on the second wiring pattern layer 121.

In other words, the first circuit board 11 and the second circuit board 12 are formed in one semiconductor manufacturing process. Alternatively, in a different embodiment, the first circuit board 11 and the second circuit board 12 are respectively formed in two different semiconductor manufacturing processes, and it is not limited herein. In addition, the manufacturing method to produce the first wiring pattern layer 111, the first dielectric layer 112, the first notches 113 and the first conductive blocks 114 in the first circuit board 11 as well as the second wiring pattern layer 121, the second dielectric layer 122, the second notches 123 and the second conductive blocks 124 in the second circuit board 12 have been described in the prior art, and the detailed description thereof is omitted herein.

In step S102, a plurality of solder balls 115 are formed on the surface of the first wiring pattern layer 111 of the first circuit board 11. In order to electrically connect the first wiring pattern layer 111 of the first circuit board 11 with the second wiring pattern layer 121 of the second circuit board 12, the solder balls 115 are formed on the first wiring pattern layer 111 for electrically connecting the first wiring pattern layer 111 to the second wiring pattern layer 121. In addition, in the present invention, before forming the solder balls 115, an arrangement for the first circuit board 11 is performed. As shown in FIG. 2C, the area of the first dielectric layer 112 without having the first conductive blocks 114 on the first circuit board 11 is removed. And then, as shown in FIG. 2D, the solder balls 115 are formed on the first wiring pattern layer 111 of the first circuit board 11. Alternatively, in a different embodiment, if the first wiring pattern layer 111 and the first conductive blocks 114 are evenly disposed in the first dielectric layer 112, the step of removing a portion of the first dielectric layer 112 may not be required and it is not limited herein.

As shown in FIG. 2E, in step S103, a plurality of conductive pillars 125 are formed on the surface of the second conductive blocks 124 of the second circuit board 12. The material of the conductive pillars 125 is preferred to be copper. However, in a different embodiment, any metals (such as copper alloy and so on) with good conductivity may be the material of the conductive pillars 125 and it is not limited herein. The conductive pillars 125 are formed by developing, masking, electroplating and washing procedures. In order to minimize the usage of the solder balls 115 in the first circuit board 11, the conductive pillars 125 are respectively disposed on the second conductive blocks 124. When the first circuit board 11 is bonding with the second circuit board 12, the usage of the solder balls 115 is minimized by the installation of the conductive pillars 125 without affecting the conductivities thereof. The usage of the solder balls 115 means a usage volume or a usage size of the solder balls 115.

Thereafter, as shown in FIG. 2F, in step S104, a plurality of bonding films 13 are formed on the surface of the second dielectric layer 122. The fabrication of the bonding films 13 includes steps of coating a bonding layer on the surface of the second dielectric layer 122 and removing a portion of the bonding layer to form the bonding films 13 around the conductive pillars 125. A cavity 131 is formed between two of the bonding films 13, and the cavity 131 is located on the surface of the conductive block 124. The bonding film 13 is configured to bond the first circuit board 11 and the second circuit board 12 together.

In step S105, by the bonding films 13, the first circuit board 11 and the second circuit board 12 are bonded together and the solder balls 115 are respectively and correspondingly coupled to the conductive pillars 125, as shown in FIG. 2G. During bonding of the first circuit board 11 and the second circuit board 12, each of the solder balls 115 corresponds to and encloses a respective one of the conductive pillars 125. Because of the installation of the conductive pillars 125 and the cavity 131 between two of the bonding films 13, the solder won't be overflowed from the cavity 131 when the solder balls 115 are integrated with the conductive pillars 125 and the usage of the solder balls 115 is reduced.

At last, in step S106, a surface treatment is performed on the surfaces of the first circuit board 11 and the second circuit board 12, and the fabrication of the structure of the multilayer printed circuit board 10 is completed, as shown in FIG. 2H. The surface treatment is to form a protecting film 14 on the surfaces of the first circuit board 11 and the second circuit board 12 to prevent hitting or damaging the multilayer printed circuit board 10.

In the present invention, by the design of the conductive pillars 125, the usage of the solder balls 115 is reduced so as to reduce the risk of overflowing of the solder balls 115 during the bonding step. Therefore, the occurrence of the short circuit in the multilayer printed circuit board 10 is decreased, and it is convenient to produce the multilayer printed circuit board with high density circuits.

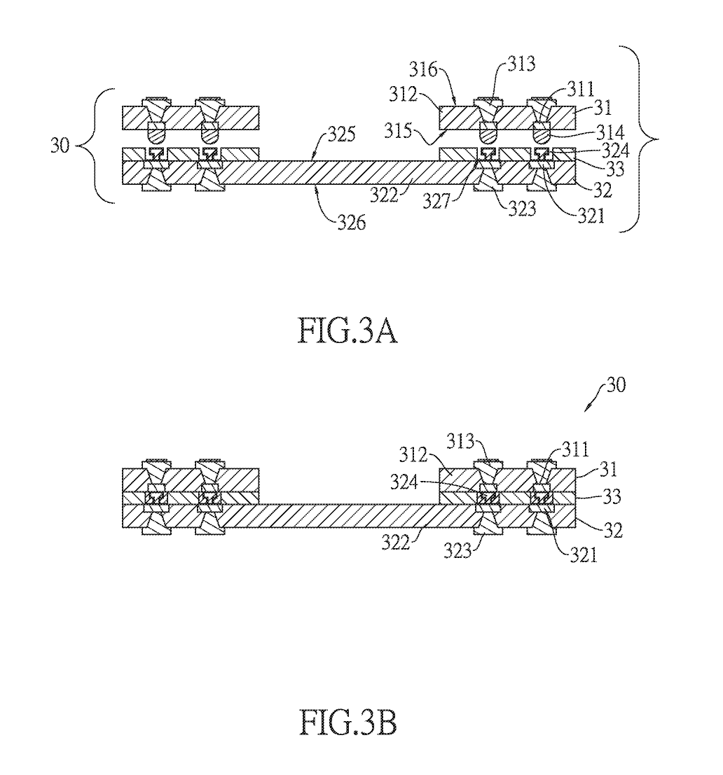

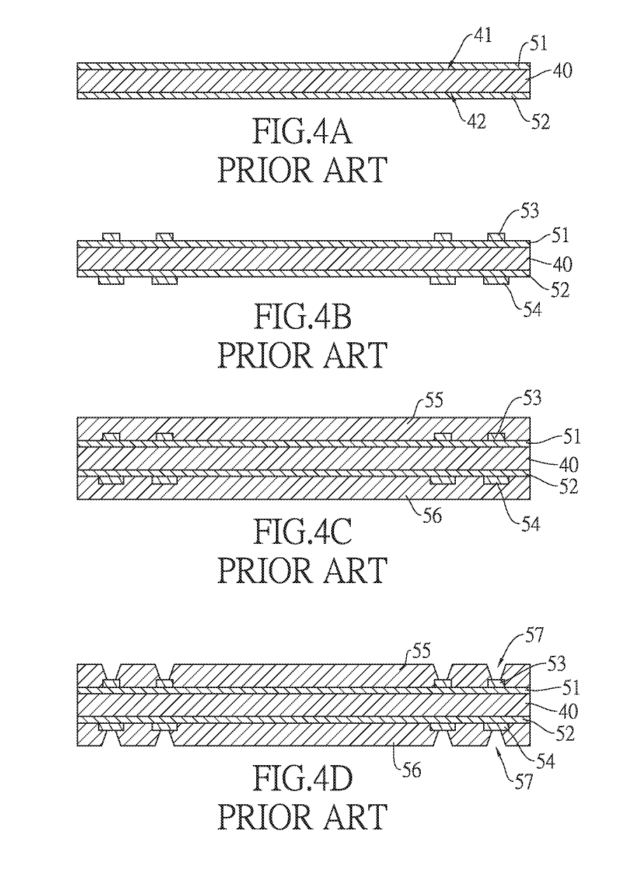

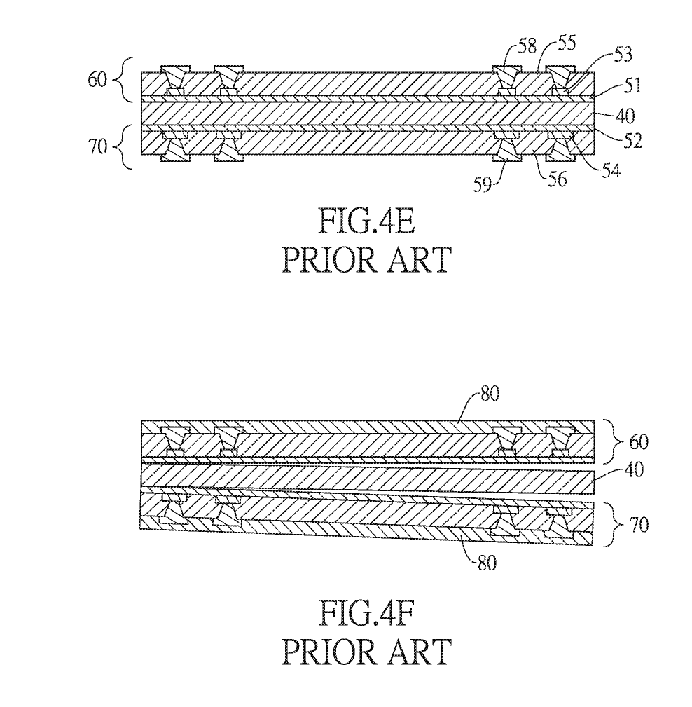

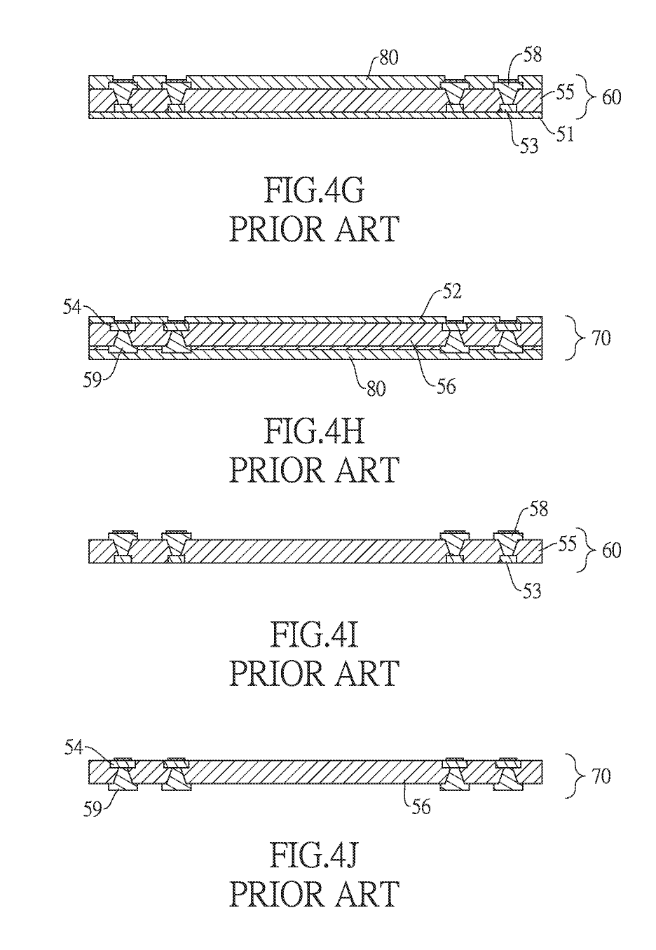

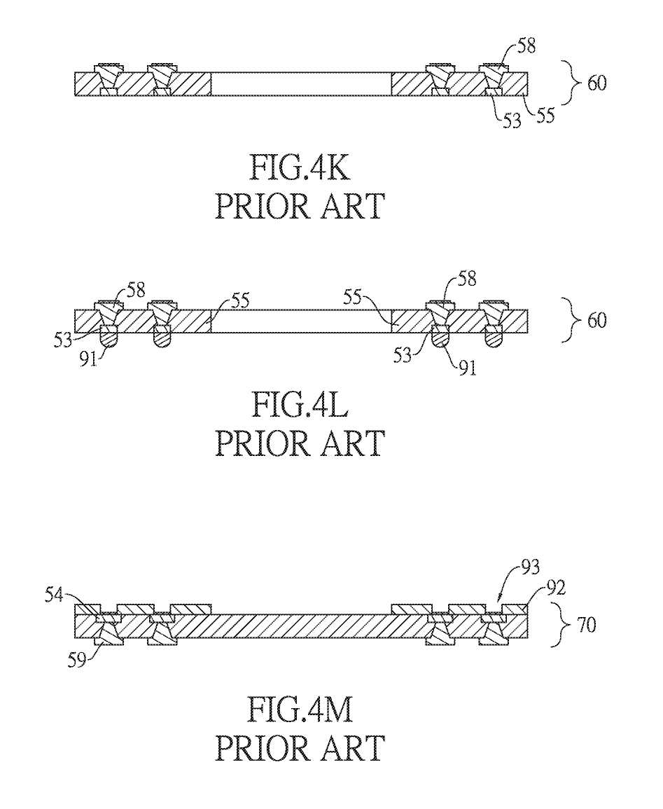

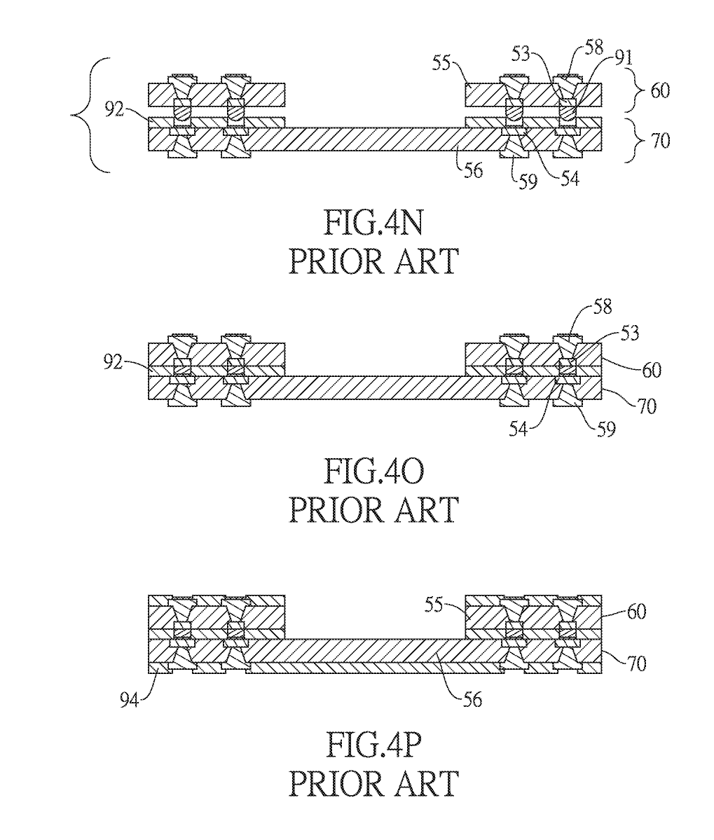

With reference to FIG. 3A and FIG. 3B, the multilayer printed circuit board 30 in the present invention includes a first circuit board 31, a second circuit board 32 and a plurality of bonding films 33. The first circuit board 31 includes a first wiring pattern layer 311, a first dielectric layer 312, a plurality of first conductive blocks 313 and a plurality of solder balls 314. The second circuit board 32 includes a second wiring pattern layer 321, a second dielectric layer 322, a plurality of second conductive blocks 323 and a plurality of conductive pillars 324.

The first dielectric layer 312 includes a first surface 315 and a second surface 316. The first wiring pattern layer 311 is formed on the first surface 315 of the first dielectric layer 312. The first conductive block 313 is formed on the second surface 316 of the first dielectric layer 312 and electrically connected to the first wiring pattern layer 311. The solder balls 314 are formed on a surface of the first wiring pattern layer 311 and electrically connected to the first wiring pattern layer 311. The second dielectric layer 322 includes a third surface 325 and a fourth surface 326. The second wiring pattern layer 321 is formed on the third surface 325 of the second dielectric layer 322. The second conductive blocks 323 are formed on the fourth surface 326 of the second dielectric layer 322 and electrically connected to the second wiring pattern layer 321. The conductive pillars 324 are formed on the surface of the second wiring pattern layer 321 and electrically connected to the second wiring pattern layer 321.

The bonding films 33 are formed on the second circuit board 32, and the first circuit board 31 and the second circuit board 32 are bonded together by the bonding films 33. The bonding films 33 include a plurality of cavities 327, and the conductive pillars 324 are located within the cavities 327 respectively. The solder balls 314 are integrated with the conductive pillar 324 respectively within the cavities 327.

Specifically, in the multilayer printed circuit board 30 of the present invention, a plurality of first notches and a plurality of second notches are respectively formed in the first dielectric layer 312 and the second dielectric layer 322 by a laser process. Thereafter, the first conductive blocks 313 and the second conductive blocks 323 are formed respectively within the first notches of the first dielectric layer 312 and the second notches of the second dielectric layer 322.

The solder balls 314 are disposed on the surface of the first conductive blocks 313 respectively. For example, by using solder paste, the solder balls 314 are disposed respectively on the surfaces of the first conductive blocks 313. There are many different ways to form the conductive pillars 324. For example, each of the conductive pillars 324 is formed on a respective one of the conductive blocks 323 by developing, masking, electroplating and cleaning process. A shape of the conductive pillar 324 is not limited to be the shape shown in drawings of the present invention. Any shape of the conductive pillar 324 capable of decreasing the usage of the solder balls 314 can be the shape of the conductive pillar 324 in the present invention. In addition, the material of the conductive pillar 324 is preferred to be copper.

Moreover, when the first circuit board 31 and the second circuit board 32 are bonded together, the solder balls 314 are correspondingly integrated with the conductive pillars 324. Therefore, each of the solder balls 314 covers a respective one of the conductive pillars 324, and each of the first conductive blocks 313 is electrically connected to a respective one of the second conductive blocks 323. Because of the implementation of the conductive pillars 324, the usage of the solder balls 314 is reduced. When the first circuit board 31 and the second circuit board 32 are bonded together, the solder balls 314 won't overflow from the cavities 327 formed in the bonding films 314, so as to prevent the occurrence of the short circuit in the multilayer circuit board 30.

By the implementation of the conductive pillars 324 in the present invention, the usage of the solder balls 314 is reduced, thereby avoiding the problem that the solder balls 314 are overflowed when the first circuit board 31 and the second circuit board 32 are bonded together.

While the present invention has been described in terms of what are presently considered to be the most practical and preferred embodiments, it is to be understood that the present invention need not be restricted to the disclosed embodiment. On the contrary, it is intended to cover various modifications and similar arrangements included within the spirit and scope of the appended claims which are to be accorded with the broadest interpretation so as to encompass all such modifications and similar structures. Therefore, the above description and illustration should not be taken as limiting the scope of the present invention which is defined by the appended claims.

1. A multilayer printed circuit board, comprising:
a first circuit board, including:
a first dielectric layer having a first surface and a second surface;
a first wiring pattern layer formed on the first surface of the first dielectric layer;
a plurality of conductive blocks formed on the second surface of the first dielectric layer and electrically connected to the first wiring pattern layer; and
a plurality of solder balls formed on a surface of the first wiring pattern layer and electrically connected to the first wiring pattern layer;
a second circuit board, including:
a second dielectric layer having a third surface and a fourth surface;
a second wiring pattern layer formed on the third surface of the second dielectric layer;
a plurality of second conductive blocks formed on the fourth surface of the second dielectric layer and electrically connected to the second wiring pattern layer; and
a plurality of conductive pillars formed on a surface of the second wiring pattern layer and electrically connected to the second wiring pattern layer; and
a plurality of bonding films formed on the second circuit board for bonding the first circuit board and the second circuit board;
wherein the solder balls and the conductive pillars are correspondingly integrated together to conduct the first wiring pattern layer and the second wiring pattern layer when the first circuit board and the second circuit board are bonded together.

2. The multilayer printed circuit board as claimed in claim 1, wherein the bonding films include a plurality of cavities and the conductive pillars are located within the cavities.

3. The multilayer printed circuit board as claimed in claim 2, wherein the solder balls are respectively integrated with the conductive pillars within the cavities.

4. The multilayer printed circuit board as claimed in claim 1, wherein the first dielectric layer includes a plurality of first notches and a plurality of second notches, and the first conductive blocks and the second conductive blocks are respectively formed within the first notches and the second notches.

5. The multilayer printed circuit board as claimed in claim 1, wherein the conductive pillars are made of copper.

6. A manufacturing method for the multilayer printed circuit board as claimed in claim 1, comprising:
forming a first circuit board and a second circuit board, wherein
the first circuit board has a first wiring pattern layer, a first dielectric layer, a plurality of first notches formed in the first dielectric layer, and a plurality of first conductive blocks formed within the first notches and disposed on the first wiring pattern layer;
the second circuit board has a second wiring pattern layer, a second dielectric layer, a plurality of second notches formed in the second dielectric layer, and a plurality of second conductive blocks formed within the second notches and disposed on the second wiring pattern layer;
forming a plurality of solder balls on a surface of the first wiring pattern layer of the first circuit board;
forming a plurality of conductive pillars on a surface of the second wiring pattern layer of the second circuit board; and
bonding the first circuit board and the second circuit board together, wherein the solder balls are respectively and correspondingly coupled to the conductive pillars.
